(19) United States
(12) Patent Application Publication
(10) Pub. No.: US 2025/0344535 A1
(43) Pub. Date: Nov. 6, 2025

(54) IMAGE SENSOR

(71) Applicant: VisEra Technologies Company Limited, Hsin-Chu City (TW)

(72) Inventors: Kuo-Fang CHUNG, Hsin-Chu City (TW); Po-Han FU, Hsin-Chu City (TW); Chin-Chuan HSIEH, Hsin-Chu City (TW)

(21) Appl. No.: 18/655,678

(22) Filed: May 6, 2024

(51) Int. Cl. H01L 27/146; G02B 1/00; G02B 5/20

(52) U.S. Cl. CPC H10F 39/806; G02B 1/002; G02B 5/208

(57) ABSTRACT

An image sensor includes a first pixel, a second pixel, a third pixel, and a fourth pixel. Each of the first, second, third, and fourth pixels includes a sensor layer, a first meta-surface layer with a first meta-pillar and disposed over the sensor layer, and a second meta-surface layer with a second meta-pillar and disposed over the first meta-surface layer. The first pixel and the third pixel are diagonally arranged, and the second pixel and the fourth pixel are diagonally arranged.

### BACKGROUND OF THE INVENTION

### Field of the Invention

The present disclosure relates to an image sensor, and in particular to an image sensor using meta-surface layers as a color filter layer.

### Description of the Related Art

Image sensors, such as complementary metal oxide semiconductor (CMOS) image sensors (also known as CIS), are widely used in various image-capturing apparatuses such as digital still-image cameras, digital video cameras, and the like. The light-sensing portion of the image sensor may detect ambient color change, and signal electric charges may be generated depending on the amount of light received in the light-sensing portion. In addition, the signal electric charges generated in the light-sensing portion may be transmitted and amplified to obtain an image signal.

Recently, meta-surfaces have garnered significant attention in the field of optics. For example, meta-surfaces may be used in conjunction with image sensors (such as a CMOS image sensor). These meta-surfaces are capable of manipulating the properties of electromagnetic waves (e.g. the incident wave). For example, these meta-surfaces may be used as lenses, polarizers, beam-shaping devices, and tunable phase modulators. Also, these meta-surfaces may be designed to correct such aberrations as spherical aberrations and chromatic aberrations. Image quality may thereby be enhanced.

However, existing meta-surfaces have not been satisfactory in all respects. In order for the finished product to maintain a high level of performance, the industry needs to improve these meta-surfaces to achieve their goal of maintaining the yield of image sensors.

### BRIEF SUMMARY OF THE INVENTION

An embodiment of the present disclosure provides an image sensor that includes a first pixel, a second pixel, a third pixel, and a fourth pixel. Each of the first, second, third, and fourth pixels includes a sensor layer, a first meta-surface layer with a first meta-pillar and disposed over the sensor layer, and a second meta-surface layer with a second meta-pillar and disposed over the first meta-surface layer. The first pixel and the third pixel are diagonally arranged, and the second pixel and the fourth pixel are diagonally arranged.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a cross-sectional view of the image sensor according to some embodiments of the present disclosure;

FIG. 2 illustrates a top view of the image sensor according to some embodiments of the present disclosure;

FIG. 3 illustrates a spectrum view of the image sensor according to some embodiments of the present disclosure;

FIG. 4 illustrates a top view of the image sensor according to some embodiments of the present disclosure;

FIG. 5 illustrates a top view of the image sensor according to some embodiments of the present disclosure;

FIG. 6 illustrates a spectrum view of the image sensor according to some embodiments of the present disclosure;

FIG. 7 illustrates a top view of the image sensor according to some embodiments of the present disclosure;

FIG. 8 illustrates a top view of the image sensor according to some embodiments of the present disclosure;

FIG. 9 illustrates a spectrum view of the image sensor according to some embodiments of the present disclosure;

FIG. 10 illustrates a top view of the image sensor according to some embodiments of the present disclosure;

FIG. 11 illustrates a top view of the image sensor according to some embodiments of the present disclosure; and

FIG. 12 illustrates a cross-sectional view of the image sensor according to other embodiments of the present disclosure.

### DETAILED DESCRIPTION OF THE INVENTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during the manufacturing process, as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the prior art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

In conventional configurations, the image sensor usually uses an additional color filter layer to ensure the desired sensing wavelength of the pixel of the image sensor. The embodiment of the present disclosure provides a novel design of the meta-surface layer, which may replace the conventional color filter layer, and the meta-surface layer may be modified to route and focus any wavelength as desired.

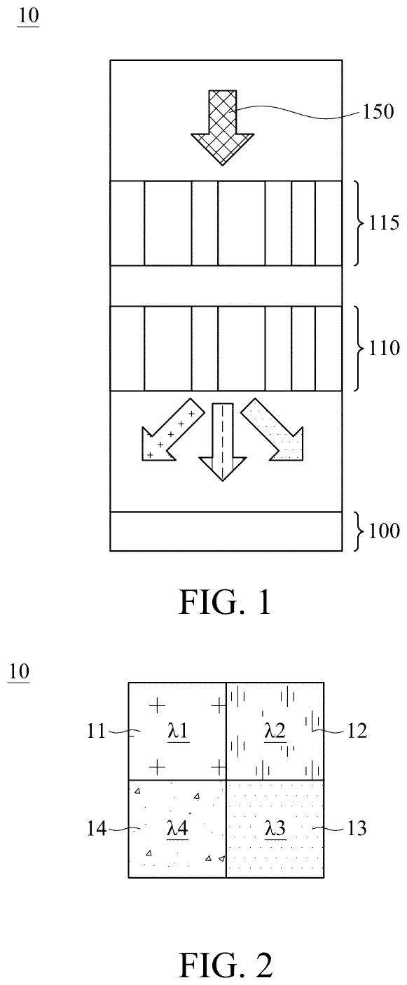

FIG. 1 illustrates a cross-sectional view of the image sensor 10 according to some embodiments of the present disclosure. FIG. 2 illustrates a top view of the image sensor 10 according to some embodiments of the present disclosure. In some embodiments, as shown in FIG. 2, the image sensor 10 includes a first pixel 11, a second pixel 12, a third pixel 13, and a fourth pixel 14. In some embodiments, the first pixel 11 and the third pixel 13 are diagonally arranged, and the second pixel 12 and the fourth pixel 14 are diagonally arranged. In some embodiments, each of the first pixel 11, the second pixel 12, the third pixel 13, and the fourth pixel 14 includes a sensor layer 100, a first meta-surface layer 110, and a second meta-surface layer 115. In some embodiments, the sensor layer 100 may form on a substrate (not shown). In some embodiments, the substrate may be an elemental semiconductor including silicon or germanium; a compound semiconductor including gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor including silicon germanium (SiGe) alloy, gallium arsenide phosphide (GaAsP) alloy, aluminum indium arsenide (AlInAs) alloy, aluminum gallium arsenide (AlGaAs) alloy, gallium indium arsenide (GaInAs) alloy, gallium indium phosphide (GaInP) alloy, and/or gallium indium arsenide phosphide (GaInAsP) alloy; or a combination thereof. In some embodiments, the substrate may be a photoelectric conversion substrate, for example, silicon substrate or organic photoelectric conversion layer. In other embodiments, the substrate may also be a semiconductor on insulator (SOI) substrate. The semiconductor on insulator substrate may include a base plate, a buried oxide layer disposed on the base plate, and a semiconductor layer disposed on the buried oxide layer. Furthermore, the substrate may be an N-type or a P-type conductive type.

In some embodiments, the sensor layer 100 may include a light-shielding layer and a sensor component (not shown). The light-shielding layer may define the region of the sensor component. The sensor component may include sensing unit, such as photodiodes, which may convert received light signals into electric signals. In some embodiments, the light-shielding layer may have a lower refractive index than the sensor component. The refractive index is a characteristic of a substance that changes the speed of light, and is a value obtained by dividing the speed of light in vacuum by the speed of light in the substance. When light travels between two different materials at an angle, its refractive index determines the angle of light transmission (refraction). When incident light enters the sensor layer 100, the light-shielding layer may isolate light rays within the specific unit to serve as the light-trapping function. In some embodiments, the material of the light-shielding layer may include a transparent dielectric material.

Still referring to FIGS. 1-2, in some embodiments, the first meta-surface layer 110 is disposed over the sensor layer 100. In some embodiments, the second meta-surface layer 115 is disposed over the first meta-surface layer 110. Generally, the meta-surface layer may provide several optical functionalities, such as phase modulation and aberration correction, and the light-collecting efficiency may be enhanced and the possibility of image distortion may be effectively reduced. When the meta-surface layer is used as the phase modulator, the phase profile of the incident wave may be manipulated. When the meta-surface layer is used as the aberration corrector, the performance of the image sensor 10 and/or the image quality may be improved. In addition, in the embodiments of the present disclosure, the first meta-surface layer 110 and the second meta-surface layer 115 further provide the functionality of light filtering. More specifically, by modifying the amount and the position of the meta-pillars 110a and 115a in the first meta-surface layer 110 and the second meta-surface layer 115, the first meta-surface layer 110 and the second meta-surface layer 115 of each of the first pixel 11, the second pixel 12, the third pixel 13, and the fourth pixel 14 may form a color filter layer of the image sensor 10. This is described in more detail below. It should be noted that the amount of the meta-pillars 110a and 115a shown in FIG. 1 is an example, and is not intended to limit the present disclosure. In some embodiments, the light 150 may pass through the first meta-surface layer 110 and the second meta-surface layer 115, and be focused onto the sensor layer 100 of the first pixel 11, the second pixel 12, the third pixel 13, or the fourth pixel 14. In some embodiments, examples of the material of the first meta-surface layer 110 and the second meta-surface layer 115 may include a dielectric material, a metal material, and the like. For example, the first meta-surface layer 110 and the second meta-surface layer 115 may be made of carbon nanotubes (CNTs), two-dimensional transition metal dichalcogenides (2D TMDs), SiC, ZrO₂, TiOₓ, SiNₓ, Indium Tin Oxides (ITO), Si, amorphous Si, polycrystalline Si, a III-V semiconductor compound, or a combination thereof. In some embodiments, the refractive index of the first meta-surface layer 110 is about 1.6 to 2.6. In some embodiments, the refractive index of the second meta-surface layer 115 is about 1.6 to 2.6.

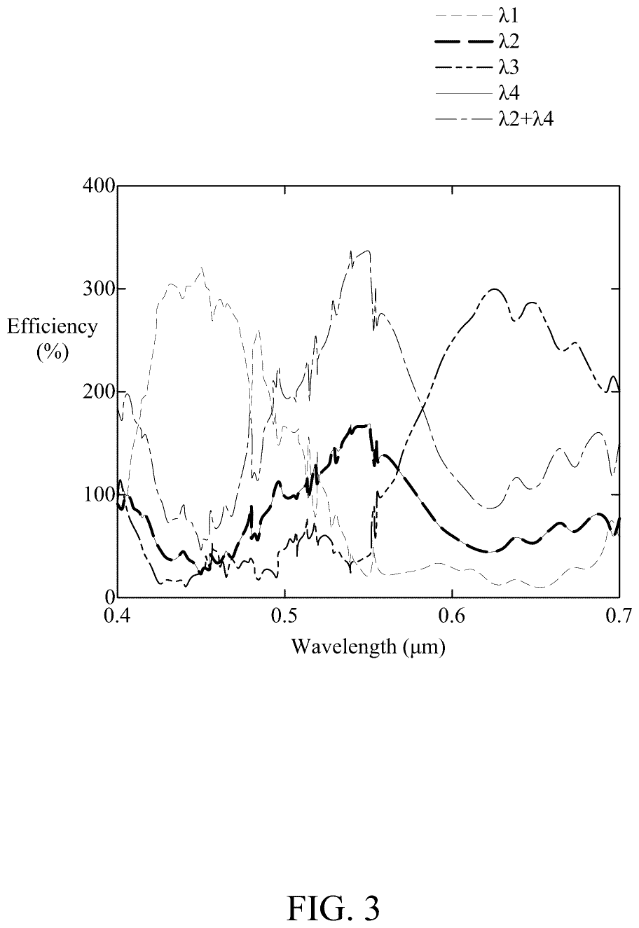

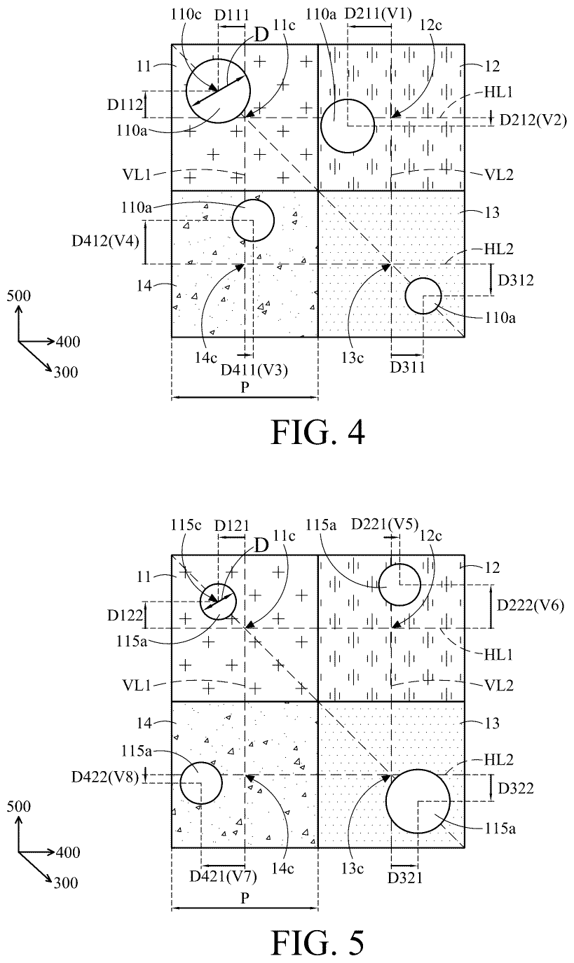

Refer to FIG. 3 and in conjunction with FIGS. 4-5. FIG. 3 illustrates a spectrum view of the image sensor 10 according to some embodiments of the present disclosure. FIG. 4 illustrates a top view of the first meta-surface layer 110 of the image sensor 10 according to some embodiments of the present disclosure. FIG. 5 illustrates a top view of the second meta-surface layer 115 of the image sensor 10 according to some embodiments of the present disclosure. In some embodiments, as shown in FIG. 3, a first sensing wavelength 21 of the first pixel 11 is less than a second sensing wavelength 22 of the second pixel 12. In some embodiments, as shown in FIG. 3, the second sensing wavelength 22 of the second pixel 12 is less than a third sensing wavelength 23 of the third pixel 13. In some embodiments, as shown in FIG. 3, a fourth sensing wavelength 24 of the fourth pixel 14 is equal to the second sensing wavelength 22 of the second pixel 12. That is, the first sensing wavelength 21, the second sensing wavelength 22, the third sensing wavelength 23, and the fourth sensing wavelength 24 satisfy the following relationship λ1<λ2=λ4<λ3. It should be noted that the efficiency shown in FIG. 3 represents the sum of the four pixels, and the maximum value of the efficiency may be greater than 100. In the embodiments of the present disclosure, the amount and the position of the meta-pillars in the first meta-surface layer 110 and the second meta-surface layer 115 are modified to form the color filter layer. For example, the amount and the position of the meta-pillars in the first meta-surface layer 110 and the second meta-surface layer 115 may be simulated and optimized by using Rigorous Coupled Wave Analysis (RCWA) and Adaptive Particle Swarm Optimization (APSO) algorithm to obtain an optimal image sensor. In some embodiments, the distance between any two adjacent meta-pillars 110a of the first meta-surface layer 110 of each of the first pixel 11, the second pixel 12, the third pixel 13, and the fourth pixel 14 is greater than 50 nm. In some embodiments, the distance between any two adjacent meta-pillars 115a of the second meta-surface layer 115 of each of the first pixel 11, the second pixel 12, the third pixel 13, and the fourth pixel 14 is greater than 50 nm. It should be noted that due to process linewidth constraints, the result of the pillar diameter or distance less than 50 nm is directly waived during the algorithm optimization process.

Still refer to FIG. 3 and in conjunction with FIGS. 4-5. In some embodiments, as shown in FIG. 4, the first meta-surface layer 110 of each of the first pixel 11, the second pixel 12, the third pixel 13, and the fourth pixel 14 includes one meta-pillar 110a. In some embodiments, as shown in FIG. 5, the second meta-surface layer 115 of each of the first pixel 11, the second pixel 12, the third pixel 13, and the fourth pixel 14 includes one meta-pillar 115a. That is, the first pixel 11 may have one meta-pillar 110a in the first meta-surface layer 110 and one meta-pillar 115a in the second meta-surface layer 115, and the meta-pillar 110a and the meta-pillar 115a of the first pixel 11 may not overlap. The embodiments shown in FIGS. 3-5 may be a Bayer pattern. In some embodiments, the diameter D of the meta-pillars 110a and 115a satisfies the following relationship 50 nm≤D. In some embodiments, the first meta-pillar 110a and the second meta-pillar 115a each has the diameter D not greater than a half of a width P of each of the first pixel 11, the second pixel 12, the third pixel 13, and the fourth pixel 14. That is, the first pixel 11, the second pixel 12, the third pixel 13, and the fourth pixel 14 have a same width P.

In some embodiments, as shown in FIGS. 4-5, a first horizontal line HL1 and a first vertical line VL1 cross each other in a center 11c of the first pixel 11. In some embodiments, the first horizontal line HL1 and a second vertical line VL2 cross each other in a center 12c of the second pixel 12. In some embodiments, a second horizontal line HL2 and the second vertical line VL2 cross each other in a center 13c of the third pixel 13. In some embodiments, the second horizontal line HL2 and the first vertical line VL1 cross each other in a center 14c of the fourth pixel 14.

In some embodiments, as shown in FIG. 4, a distance (i.e., an absolute value of the vector component D111) from a center 110c of the first meta-pillar 110a of the first pixel 11 to the first vertical line VL1 is not greater than a quarter of a width P of the first pixel 11, and is equal to a distance (i.e., an absolute value of the vector component D112) from the center 110c of the first meta-pillar 110a of the first pixel 11 to the first horizontal line HL1. In some embodiments, as shown in FIG. 4, a distance (i.e., an absolute value of the vector component D311) from a center 110c of the first meta-pillar 110a of the third pixel 13 to the second vertical line VL2 is not greater than a quarter of a width P of the third pixel 13, and is equal to a distance (i.e., an absolute value of the vector component D312) from the center 110c of the first meta-pillar 110a of the third pixel 13 to the second horizontal line HL2. In some embodiments, as shown in FIG. 5, a distance (i.e., an absolute value of the vector component D121) from a center 115c of the second meta-pillar 115a of the first pixel 11 to the first vertical line VL1 is not greater than a quarter of the width P of the first pixel 11, and is equal to a distance (i.e., an absolute value of the vector component D122) from the center 115c of the second meta-pillar 115a of the first pixel 11 to the first horizontal line HL1. In some embodiments, as shown in FIG. 5, a distance (i.e., an absolute value of the vector component D321) from a center 115c of the second meta-pillar 115a of the third pixel 13 to the second vertical line VL2 is not greater than a quarter of the width P of the third pixel 13, and is equal to a distance (i.e., an absolute value of the vector component D322) from the center 115c of the second meta-pillar 115a of the third pixel 13 to the second horizontal line HL2.

Still refer to FIG. 4. In some embodiments, a first vector component V1 (e.g., the vector component D211) in a first direction 400 and a second vector component V2 (e.g., the vector component D212) in a second direction 500 from the center 12c of the second pixel 12 to a center 110c of the first meta-pillar 110a of the second pixel 12 satisfy |V1|≤0.25·P and |V2|≤0.25·P, wherein |V1| is an absolute value of the first vector component, |V2| is an absolute value of the second vector component, and P is a width of the second pixel 12. In some embodiments, a third vector component V3 (e.g., the vector component D411) in the first direction 400 and a fourth vector component V4 (e.g., the vector component D412) in the second direction 500 from the center 14c of the fourth pixel 14 to a center 110c of the first meta-pillar 110a of the fourth pixel 14 satisfy V3=−V2 and V4=−V1.

Still refer to FIG. 5. In some embodiments, a fifth vector component V5 (e.g., the vector component D221) in the first direction 400 and a sixth vector component V6 (e.g., the vector component D222) in the second direction 500 from the center 12c of the second pixel 12 to a center 115c of the second meta-pillar 115a of the second pixel 12 satisfy |V5|≤0.25·P and |V6|≤0.25·P, wherein |V5| is an absolute value of the fifth vector component, |V6| is an absolute value of the sixth vector component. In some embodiments, a seventh vector component V7 (e.g., the vector component D421) in the first direction 400 and a eighth vector component V8 (e.g., the vector component D422) in the second direction 500 from the center 14c of the fourth pixel 14 to a center 115c of the second meta-pillar 115a of the fourth pixel 14 satisfy V7=−V6 and V8=−V5.

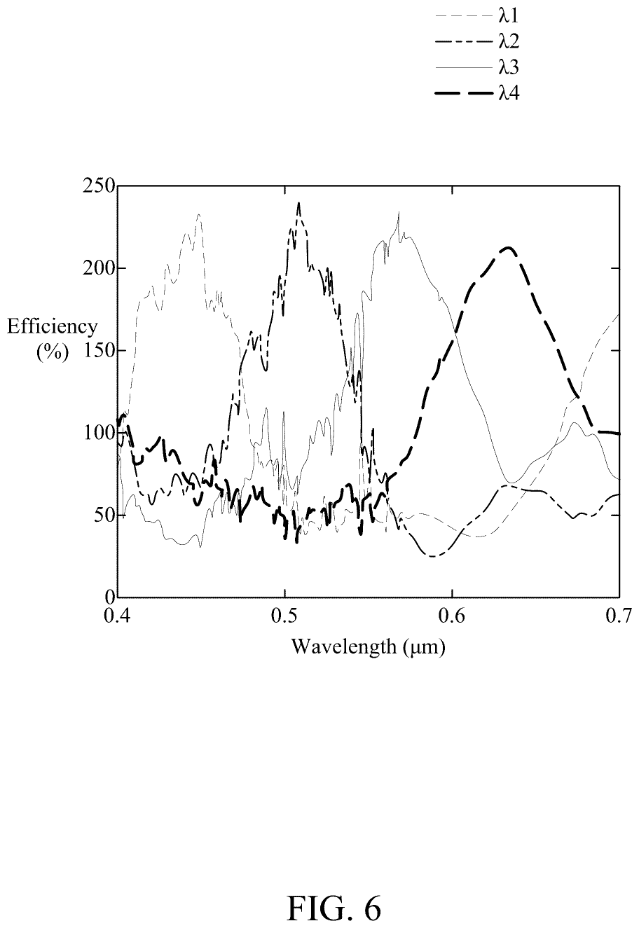

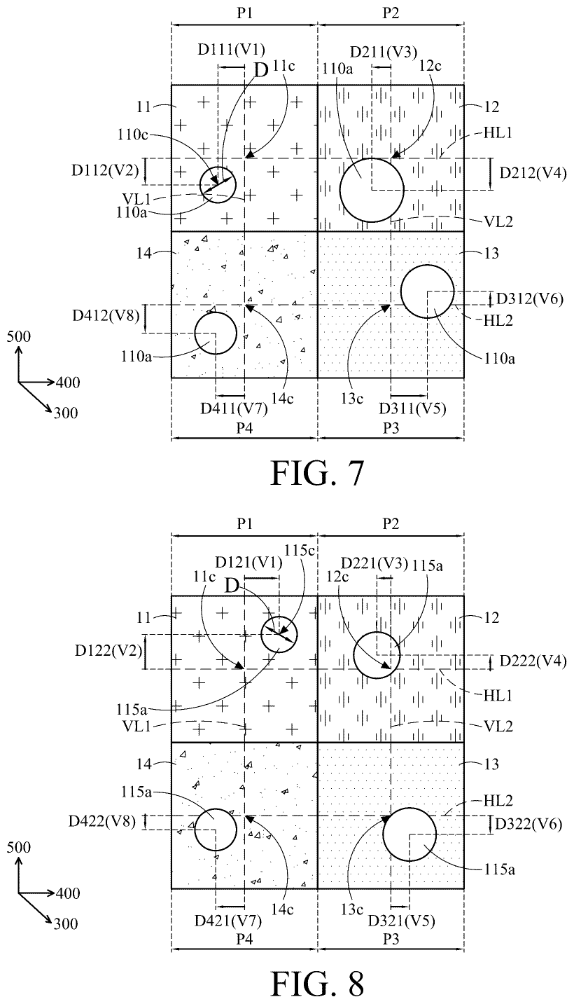

Refer to FIG. 6 and in conjunction with FIGS. 7-8. FIG. 6 illustrates a spectrum view of the image sensor 10 according to some embodiments of the present disclosure. FIG. 7 illustrates a top view of the first meta-surface layer 110 of the image sensor 10 according to some embodiments of the present disclosure. FIG. 8 illustrates a top view of the second meta-surface layer 115 of the image sensor 10 according to some embodiments of the present disclosure. FIGS. 6-8 illustrate another configuration of the sensing wavelength of each of the first pixel 11, the second pixel 12, the third pixel 13, and the fourth pixel 14. In some embodiments, the sensing wavelength λ1 of the first pixel 11, the sensing wavelength λ2 of the second pixel 12, the sensing wavelength λ3 of the third pixel 13, and the sensing wavelength λ4 of the fourth pixel 14 satisfy the following relationship ∥1<λ2<λ3<λ4. That is, the first sensing wavelength λ1 of the first pixel 11 is less than the second sensing wavelength λ2 of the second pixel 12, the second sensing wavelength λ2 of the second pixel 12 is less than the third sensing wavelength λ3 of the third pixel 13, and the third sensing wavelength λ3 of the third pixel 13 is less than the fourth sensing wavelength λ4 of the fourth pixel 14. It should be noted that the efficiency shown in FIG. 6 represents the sum of the four pixels, and the maximum value of the efficiency may be greater than 100. In some embodiments, the diameter D of the meta-pillars 110a and 115a satisfies the following relationship 50 nm≤D.

In some embodiments, as shown in FIGS. 7-8, a first horizontal line HL1 and a first vertical line VL1 cross each other in a center 11c of the first pixel 11. In some embodiments, the first horizontal line HL1 and a second vertical line VL2 cross each other in a center 12c of the second pixel 12. In some embodiments, a second horizontal line HL2 and the second vertical line VL2 cross each other in a center 13c of the third pixel 13. In some embodiments, the second horizontal line HL2 and the first vertical line VL1 cross each other in a center 14c of the fourth pixel 14.

Refer to FIG. 7. In some embodiments, a distance (i.e., an absolute value of the vector component D111) from a center 110c of the first meta-pillar 110a of the first pixel 11 to the first vertical line VL1 and a distance (i.e., an absolute value of the vector component D112) from the center 110c of the first meta-pillar 110a of the first pixel 11 to the first horizontal line HL1 are not greater than a quarter of a width P1 of the first pixel 11. In some embodiments, a distance (i.e., an absolute value of the vector component D211) from a center 110c of the first meta-pillar 110a of the second pixel 12 to the second vertical line VL2 and a distance (i.e., an absolute value of the vector component D212) from the center 110c of the first meta-pillar 110a of the second pixel 12 to the first horizontal line HL1 are not greater than a quarter of a width P2 of the second pixel 12. In some embodiments, a distance (i.e., an absolute value of the vector component D311) from a center 110c of the first meta-pillar 110a of the third pixel 13 to the second vertical line VL2 and a distance (i.e., an absolute value of the vector component D312) from the center 110c of the first meta-pillar 110a of the third pixel 13 to the second horizontal line HL2 are not greater than a quarter of a width P3 of the third pixel 13. In some embodiments, a distance (i.e., an absolute value of the vector component D411) from a center 110c of the first meta-pillar 110a of the fourth pixel 14 to the first vertical line VL1 and a distance (i.e., an absolute value of the vector component D412) from the center 110c of the first meta-pillar 110a of the fourth pixel 14 to the second horizontal line HL2 are not greater than a quarter of a width P4 of the fourth pixel 14.

Refer to FIG. 8. In some embodiments, a distance (i.e., an absolute value of the vector component D121) from a center 115c of the second meta-pillar 115a of the first pixel 11 to the first vertical line VL1 and a distance (i.e., an absolute value of the vector component D122) from the center 115c of the second meta-pillar 115a of the first pixel 11 to the first horizontal line HL1 are not greater than a quarter of the width P1 of the first pixel 11. In some embodiments, a distance (i.e., an absolute value of the vector component D221) from a center 115c of the second meta-pillar 115a of the second pixel 12 to the second vertical line VL2 and a distance (i.e., an absolute value of the vector component D222) from the center 115c of the second meta-pillar 115a of the second pixel 12 to the first horizontal line HL1 are not greater than a quarter of the width P2 of the second pixel 12. In some embodiments, a distance (i.e., an absolute value of the vector component D321) from a center 115c of the second meta-pillar 115a of the third pixel 13 to the second vertical line VL2 and a distance (i.e., an absolute value of the vector component D322) from the center 115c of the second meta-pillar 115a of the third pixel 13 to the second horizontal line HL2 are not greater than a quarter of the width P3 of the third pixel 13. In some embodiments, a distance (i.e., an absolute value of the vector component D421) from a center 115c of the second meta-pillar 115a of the fourth pixel 14 to the first vertical line VL1 and a distance (i.e., an absolute value of the vector component D422) from the center 115c of the second meta-pillar 115a of the fourth pixel 14 to the second horizontal line HL2 are not greater than a quarter of the width P4 of the fourth pixel 14.

Still refer to FIGS. 7-8. In some embodiments, a first vector component V1 (e.g., the vector component D111 or the vector component D121) in a first direction 400 and a second vector component V2 (e.g., the vector component D112 or the vector component D122) in a second direction 500 from the center 11c of the first pixel 11 to a center 110c of the first meta-pillar 110a or a center 115c of the second meta-pillar 115a of the first pixel 11 satisfy |V1|≤0.25·P1 and |V2|≤0.25·P1, wherein |V1| is an absolute value of the first vector component, |V2| is an absolute value of the second vector component, and Pl is a width of the first pixel 11. In some embodiments, a third vector component V3 (e.g., the vector component D211 or the vector component D221) in the first direction 400 and a fourth vector component V4 (e.g., the vector component D212 or the vector component D222) in the second direction 500 from the center 12c of the second pixel 12 to a center 110c of the first meta-pillar 110a or a center 115c of the second meta-pillar 115a of the second pixel 12 satisfy |V3|≤0.25·P2 and |V4|≤0.25·P2, wherein |V3| is an absolute value of the third vector component, |V4| is an absolute value of the fourth vector component, and P2 is a width of the second pixel 12. In some embodiments, a fifth vector component V5 (e.g., the vector component D311 or the vector component D321) in the first direction 400 and a sixth vector component V6 (e.g., the vector component D312 or the vector component D322) in the second direction 500 from the center 13c of the third pixel 13 to a center 110c of the first meta-pillar 110a or a center 115c of the second meta-pillar 115a of the third pixel 13 satisfy |V5|≤0.25·P3 and |V6|≤0.25·P3, wherein |V5| is an absolute value of the fifth vector component, |V6| is an absolute value of the sixth vector component, and P3 is a width of the third pixel 13. In some embodiments, a seventh vector component V7 (e.g., the vector component D411 or the vector component D421) in the first direction 400 and a eighth vector component V8 (e.g., the vector component D412 or the vector component D422) in the second direction 500 from the center 14c of the fourth pixel 14 to a center 110c of the first meta-pillar 110a or a center 115c of the second meta-pillar 115a of the fourth pixel 14 satisfy |V7|≤0.25·P4 and |V8|≤0.25·P4, wherein |V7| is an absolute value of the seventh vector component, |V8| is an absolute value of the eighth vector component, and P4 is a width of the fourth pixel 14.

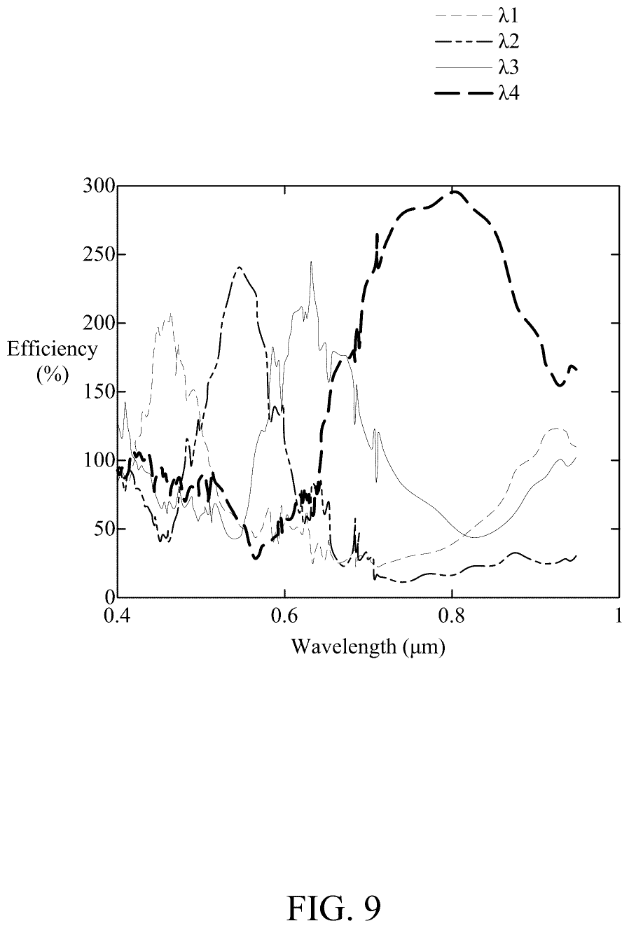

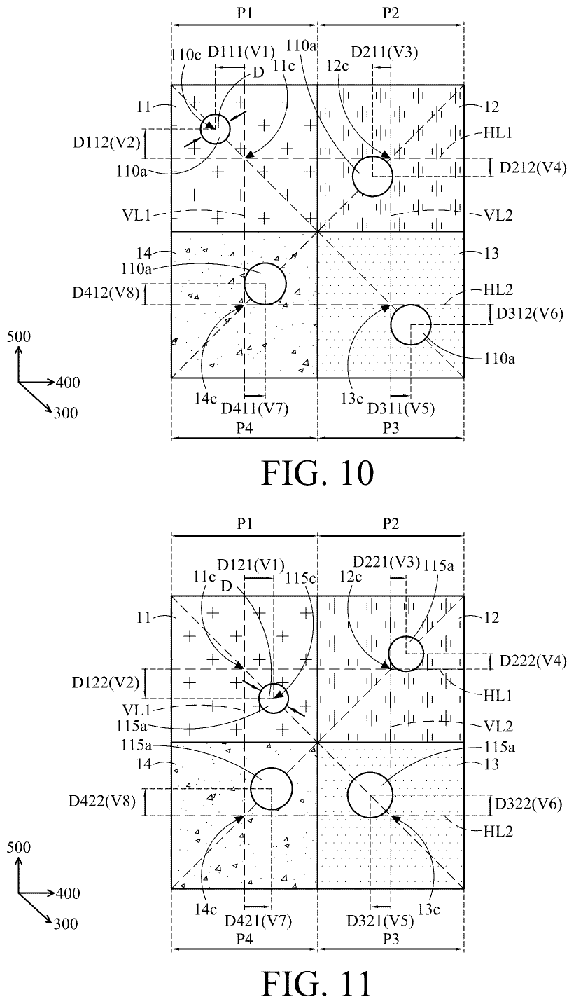

Referring to FIG. 9 and in conjunction with FIGS. 10-11. FIG. 9 illustrates a spectrum view of the image sensor 10 according to some embodiments of the present disclosure. FIG. 10 illustrates a top view of the first meta-surface layer 110 of the image sensor 10 according to some embodiments of the present disclosure. FIG. 11 illustrates a top view of the second meta-surface layer 115 of the image sensor 10 according to some embodiments of the present disclosure. FIGS. 9-11 illustrate another configuration of the sensing wavelength of each of the first pixel 11, the second pixel 12, the third pixel 13, and the fourth pixel 14. In some embodiments, the sensing wavelength λ1 of the first pixel 11, the sensing wavelength λ2 of the second pixel 12, the sensing wavelength λ3 of the third pixel 13, and the sensing wavelength λ4 of the fourth pixel 14 satisfy the following relationship λ1<λ2<λ3<λ4. That is, the first sensing wavelength λ1 of the first pixel 11 is less than the second sensing wavelength λ2 of the second pixel 12, the second sensing wavelength λ2 of the second pixel 12 is less than the third sensing wavelength λ3 of the third pixel 13, and the third sensing wavelength λ3 of the third pixel 13 is less than the fourth sensing wavelength λ4 of the fourth pixel 14. It should be noted that the efficiency shown in FIG. 9 represents the sum of the four pixels, and the maximum value of the efficiency may be greater than 100. In some embodiments, the fourth pixel 14 is an infrared (IR) sensor. In some embodiments, the diameter D of the meta-pillars 110a and 115a satisfies the following relationship 50 nm≤D.

In some embodiments, as shown in FIGS. 10-11, a first horizontal line HL1 and a first vertical line VL1 cross each other in a center 11c of the first pixel 11. In some embodiments, the first horizontal line HL1 and a second vertical line VL2 cross each other in a center 12c of the second pixel 12. In some embodiments, a second horizontal line HL2 and the second vertical line VL2 cross each other in a center 13c of the third pixel 13. In some embodiments, the second horizontal line HL2 and the first vertical line VL1 cross each other in a center 14c of the fourth pixel 14.

Refer to FIG. 10. In some embodiments, a distance (i.e., an absolute value of the vector component D111) from a center 110c of the first meta-pillar 110a of the first pixel 11 to the first vertical line VL1 is not greater than a quarter of a width P1 of the first pixel 11, and is equal to a distance (i.e., an absolute value of the vector component D112) from the center 110c of the first meta-pillar 110a of the first pixel 11 to the first horizontal line HL1. In some embodiments, a distance (i.e., an absolute value of the vector component D211) from a center 110c of the first meta-pillar 110a of the second pixel 12 to the second vertical line VL2 is not greater than a quarter of a width P2 of the second pixel 12, and is equal to a distance (i.e., an absolute value of the vector component D212) from the center 110c of the first meta-pillar 110a of the second pixel 12 to the first horizontal line HL1. In some embodiments, a distance (i.e., an absolute value of the vector component D311) from a center 110c of the first meta-pillar 110a of the third pixel 13 to the second vertical line VL2 is not greater than a quarter of a width P3 of the third pixel 13, and is equal to a distance (i.e., an absolute value of the vector component D312) from the center 110c of the first meta-pillar 110a of the third pixel 13 to the second horizontal line HL2. In some embodiments, a distance (i.e., an absolute value of the vector component D411) from a center 110c of the first meta-pillar 110a of the fourth pixel 14 to the first vertical line VL1 is not greater than a quarter of a width P4 of the fourth pixel 14, and is equal to a distance (i.e., an absolute value of the vector component D412) from the center 110c of the first meta-pillar 110a of the fourth pixel 14 to the second horizontal line HL2.

Refer to FIG. 11. In some embodiments, a distance (i.e., an absolute value of the vector component D121) from a center 115c of the second meta-pillar 115a of the first pixel 11 to the first vertical line VL1 is not greater than a quarter of the width P1 of the first pixel 11, and is equal to a distance (i.e., an absolute value of the vector component D122) from the center 115c of the second meta-pillar 115a of the first pixel 11 to the first horizontal line HL1. In some embodiments, a distance (i.e., an absolute value of the vector component D221) from a center 115c of the second meta-pillar 115a of the second pixel 12 to the second vertical line VL2 is not greater than a quarter of the width P2 of the second pixel 12, and is equal to a distance (i.e., an absolute value of the vector component D222) from the center 115c of the second meta-pillar 115a of the second pixel 12 to the first horizontal line HL1. In some embodiments, a distance (i.e., an absolute value of the vector component D321) from a center 115c of the second meta-pillar 115a of the third pixel 13 to the second vertical line VL2 is not greater than a quarter of the width P3 of the third pixel 13, and is equal to a distance (i.e., an absolute value of the vector component D322) from the center 115c of the second meta-pillar 115a of the third pixel 13 to the second horizontal line HL2. In some embodiments, a distance (i.e., an absolute value of the vector component D421) from a center 115c of the second meta-pillar 115a of the fourth pixel 14 to the first vertical line VL1 is not greater than a quarter of the width P4 of the fourth pixel 14, and is equal to a distance (i.e., an absolute value of the vector component D422) from the center 115c of the second meta-pillar 115a of the fourth pixel 14 to the second horizontal line HL2.

Still refer to FIGS. 10-11. In some embodiments, a first vector component V1 (e.g., the vector component D111 or the vector component D121) in a first direction 400 and a second vector component V2 (e.g., the vector component D112 or the vector component D122) in a second direction 500 from the center 11c of the first pixel 11 to a center 110c of the first meta-pillar 110a or a center 115c of the second meta-pillar 115a of the first pixel 11 satisfy |V1|=|V2|≤0.25·P1, wherein |V1| is an absolute value of the first vector component, |V2| is an absolute value of the second vector component, and P1 is a width of the first pixel 11. In some embodiments, a third vector component V3 (e.g., the vector component D211 or the vector component D221) in the first direction 400 and a fourth vector component V4 (e.g., the vector component D212 or the vector component D222) in the second direction 500 from the center 12c of the second pixel 12 to a center 110c of the first meta-pillar 110a or a center 115c of the second meta-pillar 115a of the second pixel 12 satisfy |V3|=|V4|≤0.25·P2, wherein |V3| is an absolute value of the third vector component, |V4| is an absolute value of the fourth vector component, and P2 is a width of the second pixel 12. In some embodiments, a fifth vector component V5 (e.g., the vector component D311 or the vector component D321) in the first direction 400 and a sixth vector component V6 (e.g., the vector component D312 or the vector component D322) in the second direction 500 from the center 13c of the third pixel 13 to a center 110c of the first meta-pillar 110a or a center 115c of the second meta-pillar 115a of the third pixel 13 satisfy |V5|=|V6|≤0.25·P3, wherein |V5| is an absolute value of the fifth vector component, |V6| is an absolute value of the sixth vector component, and P3 is a width of the third pixel 13. In some embodiments, a seventh vector component V7 (e.g., the vector component D411 or the vector component D421) in the first direction 400 and a eighth vector component V8 (e.g., the vector component D412 or the vector component D422) in the second direction 500 from the center 14c of the fourth pixel 14 to a center 110c of the first meta-pillar 110a or a center 115c of the second meta-pillar 115a of the fourth pixel 14 satisfy |V7|=|V8|≤0.25·P4, wherein |V7| is an absolute value of the seventh vector component, |V8| is an absolute value of the eighth vector component, and P4 is a width of the fourth pixel 14. In some embodiments, the first meta-pillar 110a and the second meta-pillar 115a of the first pixel 11 satisfy V1>0 and V2<0 or satisfy V1<0 and V2>0. In some embodiments, the first meta-pillar 110a and the second meta-pillar 115a of the third pixel 13 satisfy V5>0 and V6<0 or satisfy V5<0 and V6>0. In some embodiments, the first meta-pillar 110a and the second meta-pillar 115a of the second pixel 12 satisfy V3>0 and V4>0 or satisfy V3<0 and V4<0. In some embodiments, the first meta-pillar 110a and the second meta-pillar 115a of the fourth pixel 14 satisfy V7>0 and V8>0 or satisfy V7<0 and V8<0.

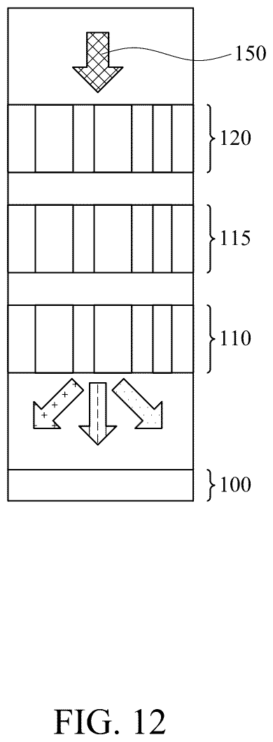

FIG. 12 illustrates a cross-sectional view of the image sensor 10 according to other embodiments of the present disclosure. FIG. 12 is similar to FIG. 1, except for the image sensor 10 further includes a third meta-surface layer 120. An additional meta-surface layer may improve the ability of the color filter, and further improve the performance of the image sensor 10 and/or the image quality.

In summary, the embodiment of the present disclosure provides a design of the meta-surface layer, including using different meta-surface layers as the color filter layer, such that the image sensor may not have to form the additional color filter layer. Further, the meta-surface layers may be customized to route and focus any sensing wavelength. Thus, the various embodiments described herein offer several advantages over the existing art. It will be understood that not all advantages have been necessarily discussed herein, no particular advantage is required for all embodiments, and other embodiments may offer different advantages.

The embodiments of the present disclosure provide an image sensor, including a first pixel, a second pixel, a third pixel, and a fourth pixel. Each of the first, second, third, and fourth pixels includes a sensor layer, a first meta-surface layer with a meta-pillar and disposed over the sensor layer, and a second meta-surface layer with a meta-pillar and disposed over the first meta-surface layer. The first pixel and the third pixel are diagonally arranged, and the second pixel and the fourth pixel are diagonally arranged.

In some embodiments, the first meta-pillar and the second meta-pillar each has a diameter not greater than a half of a width of each of the first, second, third, and fourth pixels. In some embodiments, a first horizontal line and a first vertical line cross each other in a center of the first pixel, the first horizontal line and a second vertical line cross each other in a center of the second pixel, a second horizontal line and the second vertical line cross each other in a center of the third pixel, and the second horizontal line and the first vertical line cross each other in a center of the fourth pixel.

In some embodiments, a first sensing wavelength of the first pixel is less than a second sensing wavelength of the second pixel, the second sensing wavelength of the second pixel is less than a third sensing wavelength of the third pixel, and a fourth sensing wavelength of the fourth pixel is equal to the second sensing wavelength of the second pixel. In some embodiments, a distance from a center of the first meta-pillar of the first pixel to the first vertical line is not greater than a quarter of a width of the first pixel and is equal to a distance from the center of the first meta-pillar of the first pixel to the first horizontal line, a distance from a center of the first meta-pillar of the third pixel to the second vertical line is not greater than a quarter of a width of the third pixel and is equal to a distance from the center of the first meta-pillar of the third pixel to the second horizontal line, a distance from a center of the second meta-pillar of the first pixel to the first vertical line is not greater than a quarter of the width of the first pixel and is equal to a distance from the center of the second meta-pillar of the first pixel to the first horizontal line, and a distance from a center of the second meta-pillar of the third pixel to the second vertical line is not greater than a quarter of the width of the third pixel and is equal to a distance from the center of the second meta-pillar of the third pixel to the second horizontal line.

In some embodiments, a first vector component V1 in a first direction and a second vector component V2 in a second direction from the center of the second pixel to a center of the first meta-pillar of the second pixel satisfy |V1|≤0.25·P and |V2|≤0.25·P, wherein |V1| is an absolute value of the first vector component, |V2| is an absolute value of the second vector component, and P is a width of the second pixel, and a third vector component V3 in the first direction and a fourth vector component V4 in the second direction from the center of the fourth pixel to a center of the first meta-pillar of the fourth pixel satisfy V3=−V2 and V4=−V1. In some embodiments, a fifth vector component V5 in the first direction and a sixth vector component V6 in the second direction from the center of the second pixel to a center of the second meta-pillar of the second pixel satisfy |V5|≤0.25·P and |V6|≤0.25·P, wherein |V5| is an absolute value of the fifth vector component, |V6| is an absolute value of the sixth vector component, and a seventh vector component V7 in the first direction and a eighth vector component V8 in the second direction from the center of the fourth pixel to a center of the second meta-pillar of the fourth pixel satisfy V7=−V6 and V8=−V5.

In some embodiments, a first sensing wavelength of the first pixel is less than a second sensing wavelength of the second pixel, the second sensing wavelength of the second pixel is less than a third sensing wavelength of the third pixel, and the third sensing wavelength of the third pixel is less than a fourth sensing wavelength of the fourth pixel.

In some embodiments, a distance from a center of the first meta-pillar of the first pixel to the first vertical line and a distance from the center of the first meta-pillar of the first pixel to the first horizontal line are not greater than a quarter of a width of the first pixel, a distance from a center of the first meta-pillar of the second pixel to the second vertical line and a distance from the center of the first meta-pillar of the second pixel to the first horizontal line are not greater than a quarter of a width of the second pixel, a distance from a center of the first meta-pillar of the third pixel to the second vertical line and a distance from the center of the first meta-pillar of the third pixel to the second horizontal line are not greater than a quarter of a width of the third pixel, and a distance from a center of the first meta-pillar of the fourth pixel to the first vertical line and a distance from the center of the first meta-pillar of the fourth pixel to the second horizontal line are not greater than a quarter of a width of the fourth pixel.

In some embodiments, a distance from a center of the second meta-pillar of the first pixel to the first vertical line and a distance from the center of the second meta-pillar of the first pixel to the first horizontal line are not greater than a quarter of the width of the first pixel, a distance from a center of the second meta-pillar of the second pixel to the second vertical line and a distance from the center of the second meta-pillar of the second pixel to the first horizontal line are not greater than a quarter of the width of the second pixel, a distance from a center of the second meta-pillar of the third pixel to the second vertical line and a distance from the center of the second meta-pillar of the third pixel to the second horizontal line are not greater than a quarter of the width of the third pixel, and a distance from a center of the second meta-pillar of the fourth pixel to the first vertical line and a distance from the center of the second meta-pillar of the fourth pixel to the second horizontal line are not greater than a quarter of the width of the fourth pixel.

In some embodiments, a first vector component V1 in a first direction and a second vector component V2 in a second direction from the center of the first pixel to a center of the first meta-pillar or the second meta-pillar of the first pixel satisfy |V1|≤0.25·P1 and |V2|≤0.25·P1, wherein |V1| is an absolute value of the first vector component, |V2| is an absolute value of the second vector component, and P1 is a width of the first pixel, and a third vector component V3 in the first direction and a fourth vector component V4 in the second direction from the center of the second pixel to a center of the first meta-pillar or the second meta-pillar of the second pixel satisfy |V3|≤0.25·P2 and |V4|≤0.25·P2, wherein |V3| is an absolute value of the third vector component, |V4| is an absolute value of the fourth vector component, and P2 is a width of the second pixel. In some embodiments, a fifth vector component V5 in the first direction and a sixth vector component V6 in the second direction from the center of the third pixel to a center of the first meta-pillar or the second meta-pillar of the third pixel satisfy |V5|≤0.25·P3 and |V6|≤0.25·P3, wherein |V5| is an absolute value of the fifth vector component, |V6| is an absolute value of the sixth vector component, and P3 is a width of the third pixel, and a seventh vector component V7 in the first direction and a eighth vector component V8 in the second direction from the center of the fourth pixel to a center of the first meta-pillar or the second meta-pillar of the fourth pixel satisfy |V7|≤0.25·P4 and |V8|≤0.25·P4, wherein |V7| is an absolute value of the seventh vector component, |V8| is an absolute value of the eighth vector component, and P4 is a width of the fourth pixel.

In some embodiments, a distance from a center of the first meta-pillar of the first pixel to the first vertical line is not greater than a quarter of a width of the first pixel and is equal to a distance from the center of the first meta-pillar of the first pixel to the first horizontal line, a distance from a center of the first meta-pillar of the second pixel to the second vertical line is not greater than a quarter of a width of the second pixel and is equal to a distance from the center of the first meta-pillar of the second pixel to the first horizontal line, a distance from a center of the first meta-pillar of the third pixel to the second vertical line is not greater than a quarter of a width of the third pixel and is equal to a distance from the center of the first meta-pillar of the third pixel to the second horizontal line, and a distance from a center of the first meta-pillar of the fourth pixel to the first vertical line is not greater than a quarter of a width of the fourth pixel and is equal to a distance from the center of the first meta-pillar of the fourth pixel to the second horizontal line.

In some embodiments, a distance from a center of the second meta-pillar of the first pixel to the first vertical line is not greater than a quarter of the width of the first pixel and is equal to a distance from the center of the second meta-pillar of the first pixel to the first horizontal line, a distance from a center of the second meta-pillar of the second pixel to the second vertical line is not greater than a quarter of the width of the second pixel and is equal to a distance from the center of the second meta-pillar of the second pixel to the first horizontal line, a distance from a center of the second meta-pillar of the third pixel to the second vertical line is not greater than a quarter of the width of the third pixel and is equal to a distance from the center of the second meta-pillar of the third pixel to the second horizontal line, and a distance from a center of the second meta-pillar of the fourth pixel to the first vertical line is not greater than a quarter of the width of the fourth pixel and is equal to a distance from the center of the second meta-pillar of the fourth pixel to the second horizontal line. In some embodiments, the fourth pixel is an infrared (IR) sensor.

In some embodiments, a first vector component V1 in a first direction and a second vector component V2 in a second direction from the center of the first pixel to a center of the first meta-pillar or the second meta-pillar of the first pixel satisfy |V1|=|V2|≤0.25·P1, wherein |V1| is an absolute value of the first vector component, |V2| is an absolute value of the second vector component, and P1 is a width of the first pixel, and a third vector component V3 in the first direction and a fourth vector component V4 in the second direction from the center of the second pixel to a center of the first meta-pillar or the second meta-pillar of the second pixel satisfy |V3|=|V4|≤0.25·P2, wherein |V3| is an absolute value of the third vector component, |V4| is an absolute value of the fourth vector component, and P2 is a width of the second pixel. In some embodiments, a fifth vector component V5 in the first direction and a sixth vector component V6 in the second direction from the center of the third pixel to a center of the first meta-pillar or the second meta-pillar of the third pixel satisfy |V5|=|V6|≤0.25·P3, wherein |V5| is an absolute value of the fifth vector component, |V6| is an absolute value of the sixth vector component, and P3 is a width of the third pixel, and a seventh vector component V7 in the first direction and a eighth vector component V8 in the second direction from the center of the fourth pixel to a center of the first meta-pillar or the second meta-pillar of the fourth pixel satisfy |V7|=|V8|≤0.25·P4, wherein |V7| is an absolute value of the seventh vector component, |V8| is an absolute value of the eighth vector component, and P4 is a width of the fourth pixel. In some embodiments, the first meta-pillar and the second meta-pillar of the first pixel satisfy V1>0 and V2<0 or satisfy V1<0 and V2>0, and the first meta-pillar and the second meta-pillar of the third pixel satisfy V5>0 and V6<0 or satisfy V5<0 and V6>0. In some embodiments, the first meta-pillar and the second meta-pillar of the second pixel satisfy V3>0 and V4>0 or satisfy V3<0 and V4<0, and the first meta-pillar and the second meta-pillar of the fourth pixel satisfy V7>0 and V8>0 or satisfy V7<0 and V8<0.

In some embodiments, a distance between any two adjacent ones of the first meta-pillar of each of the first, second, third, and fourth pixels is greater than 50 nm, and a distance between any two adjacent ones of the second meta-pillar of each of the first, second, third, and fourth pixels is greater than 50 nm.

The scope of the present disclosure is not limited to the technical solutions consisting of specific combinations of the technical features described above, but should also cover other technical solutions consisting of any combinations of the technical features described above or their equivalent features, all of which are within the scope of the protection of the present disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the prior art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. An image sensor, comprising:
a first pixel, a second pixel, a third pixel, and a fourth pixel, wherein each of the first, second, third, and fourth pixels comprises:
a sensor layer;
a first meta-surface layer with a first meta-pillar and disposed over the sensor layer; and
a second meta-surface layer with a second meta-pillar and disposed over the first meta-surface layer,
wherein the first pixel and the third pixel are diagonally arranged, and the second pixel and the fourth pixel are diagonally arranged.

2. The image sensor as claimed in claim 1, wherein the first meta-pillar and the second meta-pillar each has a diameter not greater than a half of a width of each of the first, second, third, and fourth pixels.

3. The image sensor as claimed in claim 1, wherein:
a first horizontal line and a first vertical line cross each other in a center of the first pixel,
the first horizontal line and a second vertical line cross each other in a center of the second pixel,
a second horizontal line and the second vertical line cross each other in a center of the third pixel, and
the second horizontal line and the first vertical line cross each other in a center of the fourth pixel.

4. The image sensor as claimed in claim 3, wherein a first sensing wavelength of the first pixel is less than a second sensing wavelength of the second pixel, wherein the second sensing wavelength of the second pixel is less than a third sensing wavelength of the third pixel, and wherein a fourth sensing wavelength of the fourth pixel is equal to the second sensing wavelength of the second pixel.

5. The image sensor as claimed in claim 4, wherein:
a distance from a center of the first meta-pillar of the first pixel to the first vertical line is not greater than a quarter of a width of the first pixel and is equal to a distance from the center of the first meta-pillar of the first pixel to the first horizontal line,
a distance from a center of the first meta-pillar of the third pixel to the second vertical line is not greater than a quarter of a width of the third pixel and is equal to a distance from the center of the first meta-pillar of the third pixel to the second horizontal line,
a distance from a center of the second meta-pillar of the first pixel to the first vertical line is not greater than a quarter of the width of the first pixel and is equal to a distance from the center of the second meta-pillar of the first pixel to the first horizontal line, and
a distance from a center of the second meta-pillar of the third pixel to the second vertical line is not greater than a quarter of the width of the third pixel and is equal to a distance from the center of the second meta-pillar of the third pixel to the second horizontal line.

6. The image sensor as claimed in claim 4, wherein:
a first vector component V1 in a first direction and a second vector component V2 in a second direction from the center of the second pixel to a center of the first meta-pillar of the second pixel satisfy |V1|≤0.25·P and |V2|≤0.25·P, wherein |V1| is an absolute value of the first vector component, |V2| is an absolute value of the second vector component, and P is a width of the second pixel, and a third vector component V3 in the first direction and a fourth vector component V4 in the second direction from the center of the fourth pixel to a center of the first meta-pillar of the fourth pixel satisfy V3=−V2 and V4=−V1.

7. The image sensor as claimed in claim 6, wherein:
a fifth vector component V5 in the first direction and a sixth vector component V6 in the second direction from the center of the second pixel to a center of the second meta-pillar of the second pixel satisfy |V5|≤0.25·P and |V6|≤0.25·P, wherein |V5| is an absolute value of the fifth vector component, |V6| is an absolute value of the sixth vector component, and
a seventh vector component V7 in the first direction and a eighth vector component V8 in the second direction from the center of the fourth pixel to a center of the second meta-pillar of the fourth pixel satisfy V7=−V6 and V8=−V5.

8. The image sensor as claimed in claim 3, wherein a first sensing wavelength of the first pixel is less than a second sensing wavelength of the second pixel, wherein the second sensing wavelength of the second pixel is less than a third sensing wavelength of the third pixel, and wherein the third sensing wavelength of the third pixel is less than a fourth sensing wavelength of the fourth pixel.

9. The image sensor as claimed in claim 8, wherein:
a distance from a center of the first meta-pillar of the first pixel to the first vertical line and a distance from the center of the first meta-pillar of the first pixel to the first horizontal line are not greater than a quarter of a width of the first pixel,
a distance from a center of the first meta-pillar of the second pixel to the second vertical line and a distance from the center of the first meta-pillar of the second pixel to the first horizontal line are not greater than a quarter of a width of the second pixel,
a distance from a center of the first meta-pillar of the third pixel to the second vertical line and a distance from the center of the first meta-pillar of the third pixel to the second horizontal line are not greater than a quarter of a width of the third pixel, and
a distance from a center of the first meta-pillar of the fourth pixel to the first vertical line and a distance from the center of the first meta-pillar of the fourth pixel to the second horizontal line are not greater than a quarter of a width of the fourth pixel.

10. The image sensor as claimed in claim 9, wherein:
a distance from a center of the second meta-pillar of the first pixel to the first vertical line and a distance from the center of the second meta-pillar of the first pixel to the first horizontal line are not greater than a quarter of the width of the first pixel,
a distance from a center of the second meta-pillar of the second pixel to the second vertical line and a distance from the center of the second meta-pillar of the second pixel to the first horizontal line are not greater than a quarter of the width of the second pixel,
a distance from a center of the second meta-pillar of the third pixel to the second vertical line and a distance from the center of the second meta-pillar of the third pixel to the second horizontal line are not greater than a quarter of the width of the third pixel, and
a distance from a center of the second meta-pillar of the fourth pixel to the first vertical line and a distance from the center of the second meta-pillar of the fourth pixel to the second horizontal line are not greater than a quarter of the width of the fourth pixel.

11. The image sensor as claimed in claim 8, wherein:
a first vector component V1 in a first direction and a second vector component V2 in a second direction from the center of the first pixel to a center of the first meta-pillar or the second meta-pillar of the first pixel satisfy |V1|≤0.25·P1 and |V2|≤0.25·P1, wherein |V1| is an absolute value of the first vector component, |V2| is an absolute value of the second vector component, and P1 is a width of the first pixel, and
a third vector component V3 in the first direction and a fourth vector component V4 in the second direction from the center of the second pixel to a center of the first meta-pillar or the second meta-pillar of the second pixel satisfy |V3|≤0.25·P2 and |V4|≤0.25·P2, wherein |V3| is an absolute value of the third vector component, |V4| is an absolute value of the fourth vector component, and P2 is a width of the second pixel.

12. The image sensor as claimed in claim 11, wherein:
a fifth vector component V5 in the first direction and a sixth vector component V6 in the second direction from the center of the third pixel to a center of the first meta-pillar or the second meta-pillar of the third pixel satisfy |V5|≤0.25·P3 and |V6|≤0.25·P3, wherein |V5| is an absolute value of the fifth vector component, |V6| is an absolute value of the sixth vector component, and P3 is a width of the third pixel, and
a seventh vector component V7 in the first direction and a eighth vector component V8 in the second direction from the center of the fourth pixel to a center of the first meta-pillar or the second meta-pillar of the fourth pixel satisfy |V7|≤0.25·P4 and |V8|≤0.25·P4, wherein |V7| is an absolute value of the seventh vector component, |V8| is an absolute value of the eighth vector component, and P4 is a width of the fourth pixel.

13. The image sensor as claimed in claim 8, wherein:
a distance from a center of the first meta-pillar of the first pixel to the first vertical line is not greater than a quarter of a width of the first pixel and is equal to a distance from the center of the first meta-pillar of the first pixel to the first horizontal line,
a distance from a center of the first meta-pillar of the second pixel to the second vertical line is not greater than a quarter of a width of the second pixel and is equal to a distance from the center of the first meta-pillar of the second pixel to the first horizontal line,
a distance from a center of the first meta-pillar of the third pixel to the second vertical line is not greater than a quarter of a width of the third pixel and is equal to a distance from the center of the first meta-pillar of the third pixel to the second horizontal line, and
a distance from a center of the first meta-pillar of the fourth pixel to the first vertical line is not greater than a quarter of a width of the fourth pixel and is equal to a distance from the center of the first meta-pillar of the fourth pixel to the second horizontal line.

14. The image sensor as claimed in claim 13, wherein:
a distance from a center of the second meta-pillar of the first pixel to the first vertical line is not greater than a quarter of the width of the first pixel and is equal to a distance from the center of the second meta-pillar of the first pixel to the first horizontal line,
a distance from a center of the second meta-pillar of the second pixel to the second vertical line is not greater than a quarter of the width of the second pixel and is equal to a distance from the center of the second meta-pillar of the second pixel to the first horizontal line,
a distance from a center of the second meta-pillar of the third pixel to the second vertical line is not greater than a quarter of the width of the third pixel and is equal to a distance from the center of the second meta-pillar of the third pixel to the second horizontal line, and
a distance from a center of the second meta-pillar of the fourth pixel to the first vertical line is not greater than a quarter of the width of the fourth pixel and is equal to a distance from the center of the second meta-pillar of the fourth pixel to the second horizontal line.

15. The image sensor as claimed in claim 14, wherein the fourth pixel is an infrared (IR) sensor.

16. The image sensor as claimed in claim 8, wherein:
a first vector component V1 in a first direction and a second vector component V2 in a second direction from the center of the first pixel to a center of the first meta-pillar or the second meta-pillar of the first pixel satisfy |V1|=|V2|≤0.25·P1, wherein |V1| is an absolute value of the first vector component, |V2| is an absolute value of the second vector component, and P1 is a width of the first pixel, and
a third vector component V3 in the first direction and a fourth vector component V4 in the second direction from the center of the second pixel to a center of the first meta-pillar or the second meta-pillar of the second pixel satisfy |V3|=|V4|≤0.25·P2, wherein |V3| is an absolute value of the third vector component, |V4| is an absolute value of the fourth vector component, and P2 is a width of the second pixel.

17. The image sensor as claimed in claim 16, wherein:
a fifth vector component V5 in the first direction and a sixth vector component V6 in the second direction from the center of the third pixel to a center of the first meta-pillar or the second meta-pillar of the third pixel satisfy |V5|=|V6|≤0.25·P3, wherein |V5| is an absolute value of the fifth vector component, |V6| is an absolute value of the sixth vector component, and P3 is a width of the third pixel, and
a seventh vector component V7 in the first direction and a eighth vector component V8 in the second direction from the center of the fourth pixel to a center of the first meta-pillar or the second meta-pillar of the fourth pixel satisfy |V7|=|V8|≤0.25·P4, wherein |V7| is an absolute value of the seventh vector component, |V8| is an absolute value of the eighth vector component, and P4 is a width of the fourth pixel.

18. The image sensor as claimed in claim 17, wherein:
the first meta-pillar and the second meta-pillar of the first pixel satisfy V1>0 and V2<0 or satisfy V1<0 and V2>0, and
the first meta-pillar and the second meta-pillar of the third pixel satisfy V5>0 and V6<0 or satisfy V5<0 and V6>0.

19. The image sensor as claimed in claim 18, wherein:
the first meta-pillar and the second meta-pillar of the second pixel satisfy V3>0 and V4>0 or satisfy V3<0 and V4<0, and
the first meta-pillar and the second meta-pillar of the fourth pixel satisfy V7>0 and V8>0 or satisfy V7<0 and V8<0.

20. The image sensor as claimed in claim 1, wherein a distance between any two adjacent ones of the first meta-pillar of each of the first, second, third, and fourth pixels is greater than 50 nm, and a distance between any two adjacent ones of the second meta-pillar of each of the first, second, third, and fourth pixels is greater than 50 nm.
